(19) United States
(12) Patent Application Publication
(10) Pub. No.: US 2006/0183329 A1
(43) Pub. Date: Aug. 17, 2006

(54) Apparatus and method for reducing impurities in a semiconductor material

(75) Inventors: Charles Leung, Cerritos, CA (US); David Zhang, Fremont, CA (US); Morris Young, Fremont, CA (US)

Correspondence Address: AKERMAN SENTERFITT, 801 PENNSYLVANIA AVENUE N.W., SUITE 600, WASHINGTON, DC, 20004, US

(73) Assignee: AXT, Inc., Fremont, CA (US)

(21) Appl. No.: 10/547,772

(22) PCT Filed: Mar. 2, 2004
(86) PCT No.: PCT/US04/06187

§ 371 Date: Sep. 2, 2005

Related U.S. Application Data
(63) Continuation-in-part of application No. 10/377,769, filed on Mar. 4, 2003, now abandoned.

(51) Int. Cl. C03C 15/00; H01L 21/302; H01L 21/306

(52) U.S. Cl. 438/689; 216/57; 156/345.37

(57) ABSTRACT

An apparatus and method of treating multiple wafers to reduce the density of impurities as well as to improve the uniformity of substrate electrical characteristics without any thermal stress. The wafers are chemically treated, and heat treated in a sealed reaction tube under arsenic overpressure with a controlled thermal profile to heat the wafers. The thermal profile controls temperature of different zones inside of a furnace containing the sealed reaction tube. Impurities of the wafers are dissolved, and are out-diffused from the inner portions to the outer portions of the wafers.

The present invention relates to the treatment of a semiconductor material. More particularly, the invention relates to apparatuses and methods for reducing impurities and/or defects in a semiconductor material.

### BACKGROUND OF THE INVENTION

A semiconductor integrated circuit (IC) is formed on a semiconductor substrate, such as a wafer. The quality of the crystal property within the wafer and near the wafer surface plays an important role. In particular, electrical characteristics are of vital importance for IC devices, and such electrical characteristics are influenced by crystal defects and/or impurities within the substrate and near the surface of the substrate. For example, semi-conducting Gallium Arsenide (“GaAs”) material used in opto-electronic IC applications as well as semi-insulating GaAs material used in ultra-high-speed digital circuits require tight control of impurity incorporation and homogenous distribution of defects.

In semiconductor material, undesirable impurities and the existence of defects, such as arsenic precipitates in bulk material, contribute to high density of Light Point Defects (LPDs) in the substrate. The dimension of these arsenic precipitates range between 500-2,000 Å. This high density of LPDs in surface, near surface, and interfaces, formed from impurities/defects in bulk material, are generated during various steps of wafer processing. Specifically, significant LPDs are found on polished surfaces of wafer slices made from wafer processing. The LPDs contribute to the microscopic inhomogeneities in the surface of the wafer slices. These surface and near surface defects lead to the formation of microscopic surface defects on epitaxial layers. For example, gettering of arsenic and impurities by dislocations may result in a heavily disordered core region surrounded by a large region free of defects and impurities as well as small and large arsenic clusters in the wafer slices. These heavily disordered core regions exist in the wafer slices in varying sizes, and form the basis of high density LPDs. These LPDs on the wafer slices are readily detected by various laser light scattering techniques and by high intensity light illumination equipment The impurities/defects affect the performance, properties and yield of final IC devices made from the wafer slices.

Ingot annealing through high temperature thermal treatment after crystal growth of an ingot has been a standard part of wafer production process. However, ingot annealing is not effective in decreasing the density of LPDs or in improving uniformity of the material in wafer slices fabricated from the ingot. In fact, ingot annealing has the inherent shortcoming of increasing dislocation density due to high thermal stress. High temperature thermal treatment has the potential to degrade crystal stoichiometry and increase dislocation density due to high thermal stress. Moreover, ingot annealing is not effective in improving microscopic homogeneities because high temperature treatment mainly involves the redistribution of these arsenic precipitates and impurities clusters. Substrates, such as wafer slices, made from the above-described ingot still contain high density of impurities/defects. Therefore, there is a need for an apparatus and a method that reduce high density LPDs while improving the uniformity of the electrical characteristics.

### SUMMARY OF THE INVENTION

Aspects of the present invention relate to an apparatus and method for reducing impurities in a semiconductor material, such as wafer slices and other type of substrates. One embodiment of the present invention relates to a multiple-wafer-thermal-treatment (MWTT) method of GaAs wafer slices to reduce the density of LPDs as well as to improve the uniformity of substrate electrical characteristics with reduced thermal stress.

The process includes the sequential steps of chemically treating the wafer slices and heat treating the wafer slices in a sealed ampoule under arsenic overpressure with a controlled thermal profile. The MWTT method involves in one aspect, the dissolution of arsenic precipitates and other impurities in the wafer slices and controlling the diffusion of the dissolved arsenic precipitates and other impurities to the surface and near-surface regions, or outer zone portions, of the wafer slices.

In particular, the present invention includes a method of treating a plurality of wafer slices having impurities, the wafer slices including inner zone portions and outer zone portions, at least a portion of the impurities situated on the inner zone portions, the method including loading a predetermined amount of arsenic into a reaction tube containing the plurality of wafer slices; loading the reaction tube into a furnace capable of having a plurality of zones; controlling temperature of the zones inside of the furnace with a thermal profile so that the impurities of the plurality of wafer slices are diffused from the inner zone portions to the outer zone portions of the plurality of wafer slices; removing the plurality of wafer slices from the reaction tube; and polishing the plurality of wafer slices to remove the outer zone portions of the plurality of wafer slices containing the impurities.

In another aspect of the present invention, a method of treating a plurality of substrates having impurities below surface regions of the substrates, includes chemically treating the substrates; loading the plurality of substrates onto a substrate holder; loading the substrate holder into a reaction tube; loading a predetermined amount of arsenic into the reaction tube; evacuating the reaction tube to remove at least one of residual moisture and gas; sealing the reaction tube under vacuum; loading the sealed reaction tube into a furnace, wherein the furnace has multiple heat zones to control temperature in various locations of the reaction tube; heating the sealed reaction tube with a specific temperature profile to effect dissolution of impurities and diffusion of the dissolved impurities to the surface regions of the substrates; cooling the sealed reaction tube; removing the plurality of substrates from the reaction tube; and polishing the plurality of substrates to remove portion of the surface regions containing the impurities.

In yet another aspect of the present invention, an apparatus for treating a plurality of wafer slices to reduce light point defects, includes a zone furnace; a reaction tube within the zone furnace; arsenic repository in the reaction tube to allow a predetermined amount of arsenic to be placed into the reaction tube; a wafer slices holder in the reaction tube, the wafer slices holder allowing a plurality of wafer slices to be held for treatment; and a plurality of heating elements surrounding the reaction tube to control temperature of different zones inside of the zone furnace with a thermal profile.

Finally, in yet another aspect of the present invention, a method of treating semiconductor material includes loading a predetermined amount of arsenic into a reaction tube containing the semiconductor material, the arsenic providing arsenic overpressure at high temperature; loading the reaction tube into a furnace; controlling temperature of different zones inside of the furnace with a thermal profile so that impurities of the semiconductor material are out-diffused to outer zone portions of the semiconductor material; removing the semiconductor material from the reaction tube; and polishing the semiconductor material to remove the outer zone portions of the semiconductor material containing impurities.

There has thus been outlined, rather broadly, some features consistent with the present invention in order that the detailed description thereof that follows may be better understood, and in order that the present contribution to the art may be better appreciated. There are, of course, additional features consistent with the present invention that will be described below and which will form the subject matter of the claims appended hereto.

In this respect, before explaining at least one embodiment consistent with the present invention in detail, it is to be understood that the invention is not limited in its application to the details of construction and to the arrangements of the components set forth in the following description or illustrated in the drawings. Methods and apparatuses consistent with the present invention are capable of other embodiments and of being practiced and carried out in various ways. Also, it is to be understood that the phraseology and terminology employed herein, as well as the abstract included below, are for the purpose of description and should not be regarded as limiting.

As such, those skilled in the art will appreciate that the conception upon which this disclosure is based may readily be utilized as a basis for the designing of other structures, methods and systems for carrying out the several purposes of the present invention. It is important, therefore, that the claims be regarded as including such equivalent constructions insofar as they do not depart from the spirit and scope of the methods and apparatuses consistent with the present invention.

### BRIEF DESCRIPTION OF THE DRAWINGS

FIG. 1 shows a cross-sectional view of an apparatus for treating a number of wafer slices to dissolve and redistribute impurities within the wafer slices according to an embodiment of the present invention;

FIG. 2 is a flowchart which illustrates processes for reducing impurities in a number of wafer slices according to an embodiment of the present invention;

FIG. 3 is a flowchart which illustrates processes for loading a number of wafer slices to be treated into a furnace according to an embodiment of the present invention; and

FIG. 4 is a flowchart which illustrates processes for controlling temperature inside the furnace with a thermal profile to dissolve and redistribute impurities within the wafer slices according to an embodiment of the present invention.

### DETAILED DESCRIPTION OF THE PREFERRED EMBODIMENTS

Each embodiment of the present invention is directed to an apparatus and method for reducing impurities in a semiconductor material. In one embodiment, the semiconductor material is in the form of a number of substrates, such as wafer slices, and the embodiment relates to the wafer processing of Group III-v or Group II-VI monocrystalline compound. Monocrystalline Group II-VI and III-V compounds may be referred to as semiconductors with resistivities typically within the broad range between 1×10⁻³ to 10⁹ ohm-cm. Group II-VI and III-V monocrystalline compounds having resistivities greater than about 1×10⁷ ohm-cm are referred to as semi-insulators. Depending on the Group II-VI and III-V compound, the monocrystalline form may be semi-insulating in its undoped or intrinsic state, or in a doped state. Examples of monocrystalline form in a doped state include GaAs with chromium or carbon as a dopant or Indium Phosphate (InP) with iron as a dopant.

According to one embodiment of the present invention, the method for reducing impurities in the wafer slices may be referred to as the multiple-wafer-thermal-treatment (MWTT) process. The MWTT process includes the chemical treatment of the wafer slices and the thermal treatment of the wafer slices under vacuum in a sealed reaction tube. In one embodiment, the reaction tube is a quartz ampoule. For purposes of description, the terms quartz, fused quartz and fused silica may be used interchangeably and all refer to the entire group of materials made by fusing silica (SiO₂). In the embodiment, the wafer slices is positioned in a specific manner in the reaction tube. The wafer slices are thermally treated under arsenic overpressure with a pre-determined thermal profile program to dissolve the arsenic precipitates and impurities for LPDs reduction. The term LPDs may be referred to as bright scattering points on the surface of substrate or surface that can be detected by laser light scattering equipment (e.g., Tencor Surfscan®) or by illumination of high intensity diffused light illumination with a luminous intensity greater than, for example, 50,000 Lux.

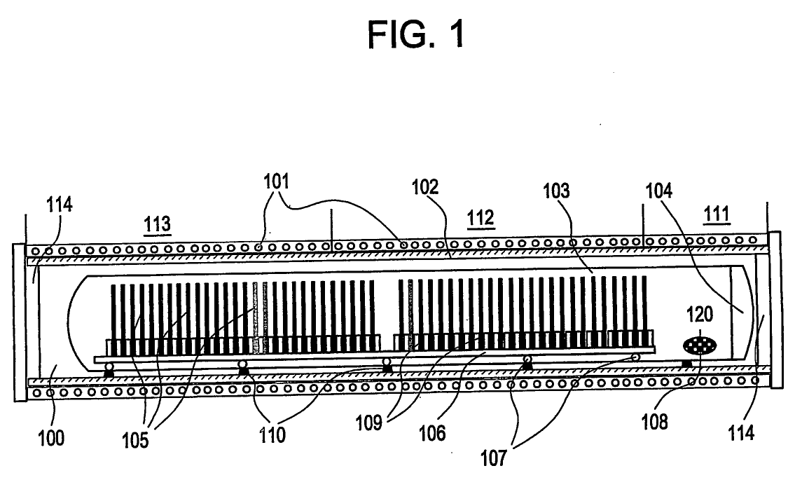

FIG. 1 illustrates a cross-sectional view of an apparatus for treating a number of wafer slices 105 to reduce impurities and/or defects within the wafer slices 105 according to an embodiment of the present invention. The apparatus includes a furnace 100, a liner 102, furnace caps 114, a reaction tube 103 within the furnace 100, a number of heating elements 101, an arsenic repository 108 and a wafer slices holder 106 having wafer slots 109. The wafer slices holder 106 allows the wafer slices to be held for treatment. In one embodiment, the wafer slices 105 to be treated are held in a vertical free position with minimal contact in the wafer slots 109. These wafer slots 109 have a specific radius built into them to match the curvature of the wafer edge profile of the wafer slices 105. The wafer slices holder 106 may be fabricated with multiple supporting points 107 for reinforcement.

During operation, a predetermined amount of elemental arsenic 120 needs to be loaded into the reaction tube 103 along with the wafer slices 105. In one embodiment, the pre-determined amount of the arsenic 120 loaded into the reaction tube 103 is sufficient to maintain adequate arsenic vapor pressure to preserve stoichiometric composition of semiconductor material that makes up the wafer slices 105. In a preferred embodiment, the predetermined amount of arsenic 120 is placed in or on the arsenic repository 108 in the reaction tube 103, wherein the arsenic repository 108 is located near the open end of the reaction tube 103, or any location capable of being controlled under a temperature different from those of other locations of the furnace 100. In another embodiment, the arsenic repository 108 may be connected to the reaction tube 103, and arsenic vapor is provided to the reaction tube 103 on an as-needed basis.

The reaction tube 103 is preferably a quartz tube, which needs to be sealed after the wafer slices 105 and the elemental arsenic 120 are loaded into the reaction tube 103. In one embodiment, the tube is evacuated to a vacuum level of ˜1×10⁻⁵ torr, and sealing of the quartz tube 103 under vacuum is accomplished by melting the quartz plug 104 with a high temperature flame. The sealed reaction tube 103, with the wafer slices 105 and the elemental arsenic 120 inside, is then loaded into the furnace 100 with the liner 102 on the quartz supports 110. Furnace caps 114 are then placed on the ends of the furnace 100.

The heating elements 101 surround the reaction tube 103 and control temperature of different zones inside of the furnace 100 with a thermal profile. According to an embodiment of the present invention, these heating elements 101 are arranged in groups, adjacent to the sealed reaction tube 103, in three temperature zones 111, 112, 113. For simplicity, only three temperature zones 111, 112, 113 are shown here. It is noted that more than three temperature zones are used for exceptionally precise temperature control requirement. In one embodiment, power is applied to the different temperature zones 111, 112, 113 to raise the temperature for the thermal treatment process. Typically, temperatures in the initial heating stage and the cooling stage are controlled in such a way that an excessive amount of arsenic will not be deposited on any portion of the wafer surface of the wafer slices 105 during the thermal treatment process. Condensation of arsenic is controlled by maintaining differential temperatures in the temperature zones, e.g., zone 112 containing a portion of the wafer slices 105, zone 113 containing another portion of the wafer slices 105, and zone 111 containing the elemental arsenic 120.

The MWTT process capable of performing by the apparatus shown in FIG. 1, and those similar thereto, overcomes the disadvantages of stoichiometry degradation and high thermal stress inherent by conventional high temperature treatment. The MWTT process comprises the chemical treatment of the wafer slices and the thermal treatment of the wafer slices to cause the dissolution of arsenic precipitates and impurities clusters as well as the diffusion of the dissolved species away from the core of the wafer slices to the surface and near surface portions of the wafer slices. The outer regions of the wafer slices are then removed in subsequent wafer processing steps.

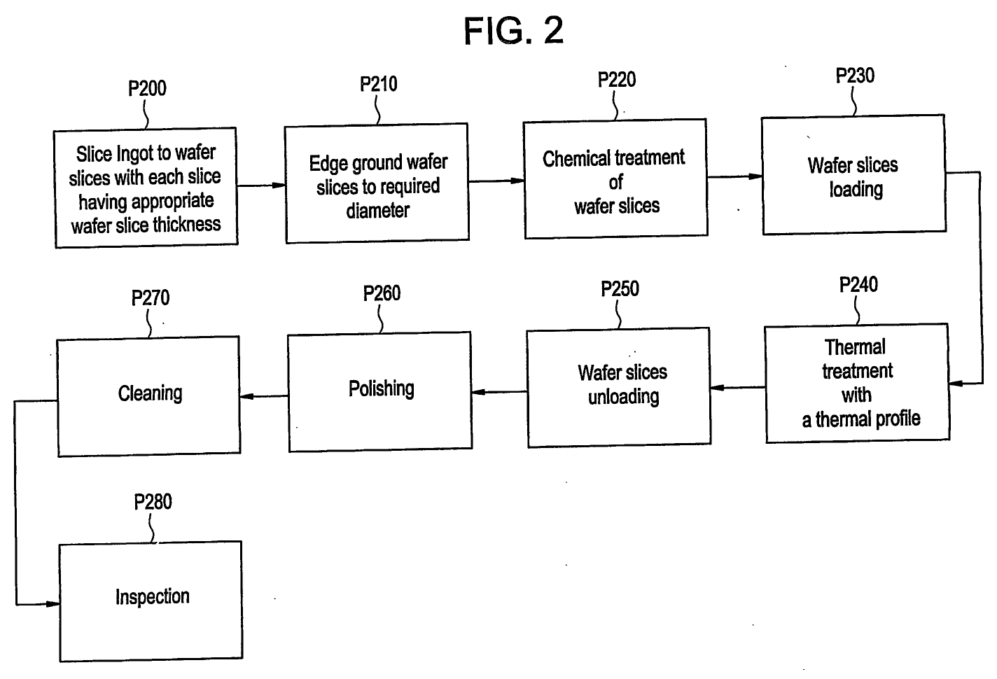

FIG. 2 illustrates the MWTT process for dissolving and redistributing impurities/defects in a number of substrates, such as wafer slices, according to an embodiment of the present invention. In step P200, an ingot is sliced into a number of wafer slices, each having an appropriate predetermined wafer slice thickness. In one embodiment, the appropriate wafer slice is in the range of 500 μm to 1200 μm. In step P210, edge grinding is performed on the wafer slices, where the wafer slices are edge ground to required diameter, which may range from 50 mm to 150 mm according to embodiments of the present invention.

Chemical treatment of the wafer slices is then performed in step P220, with only the top surface condition of the wafer slice being disturbed. Chemical treatment is important not only in eliminating any extraneous/surface contaminants that may have impact on the bulk characteristics but also in preparing the surface condition that can getter the dissolved impurities under the high temperature treatment scheme. This allows potential detrimental surface impurities to be removed and preserves the as-cut surface and near surface condition. In one embodiment, chemical etching is carried out in batches with chemicals that comprise oxidizing agents and complexing agents. For example, NH₄OH:H₂O₂:H₂O in a 1:1:1 ratio may be used.

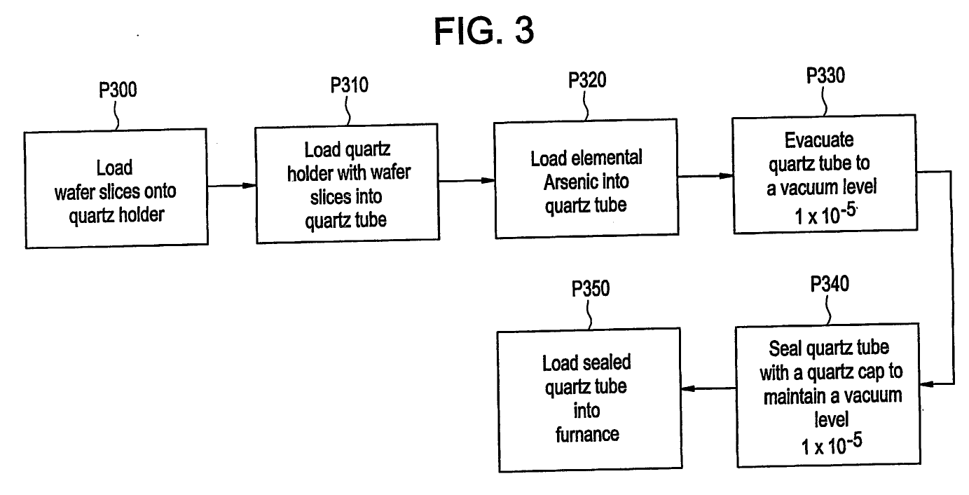

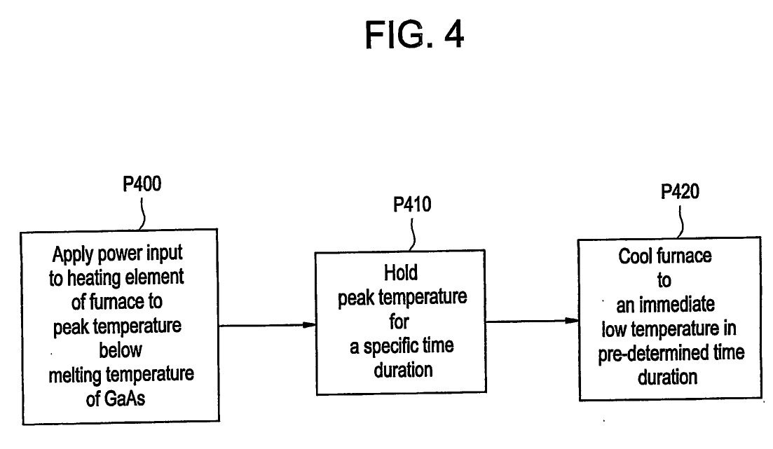

In step P230, the chemically treated wafer slices are loaded into a reaction tube, which is then loaded into a furnace. The wafer slices loading process, which also includes loading a predetermined amount of arsenic that provides an arsenic overpressure during the subsequent thermal treatment process, will be described in more detail with respect to FIG. 3 in a later section. After the wafer slices are loaded properly, thermal treatment of the wafer slices, via a predetermined thermal profile, is accomplished in a sealed reaction tube with the appropriate amount of arsenic in step P240. An illustrative example of a thermal treatment with an exemplary thermal profile is described in more detail with respect to FIG. 4 in a later section.

In the thermal treatment of the wafer slices of step P240, time and temperature of the thermal treatment process are important to the reduction of LPDs and the improvement of bulk material uniformity. In one embodiment, the reduction of the LPDs depends on the control of the redistribution of the dissolved species in the inner zone regions, which includes the core region of the wafer slices. Moreover, time and temperature of the thermal treatment process is dependent on the wafer slice thickness. Since the dissolved impurities are out-diffused away from the core of the wafer slice at high temperatures to one end (i.e., near the surface of the wafer), a concentration gradient of the dissolved species is established. By the control of the thermal profile in the zone region, and surface conditions, the dissolved species are accumulated in the outer zone regions of the wafer slices, which includes the surface of the wafer slices and the near-surface of the wafer slices.

To reduce impurities, in the form of defects and heavily disordered regions, thermal treatment profiles with specific parameters are designed to dissolve and redistribute the impurities/defects in the bulk substrates made with different semiconductor material. Naturally, the thermal treatment profile cannot be greater than the transition temperature (i.e., melting temperature) of the material. The thermal treatment process requires not only the design of an effective thermal profile to redistribute these impurities/defects in a smaller size or form as well as in different location but also the control of the different process and substrate parameters that have major impact in the total elimination of these impurities/defects from the substrates. Different thermal profiles have been developed to achieve the reduction of LPDs and to improve the electrical uniformity of the bulk materials. The thermal profile allows different temperatures for the various zones in the furnace to be created to effectively dissolve the arsenic precipitates and impurities clusters under an arsenic overpressure. The thermal profile further controls the cooling of the wafer slices after dissolution of the arsenic precipitates and other impurities, such that the excessive amount of the arsenic and other impurities are out-diffused to the outer zone portions of the wafer slices from the inner zone portions of the wafer slices.

In step P250, the wafer slices are unloaded from the furnace after undergoing thermal treatment with a particular thermal profile. In step P260, the outer zone portions of the wafer slices, from the front and back surface regions of the wafer slices, are removed using a combination of chemical etching and polishing processes. Conventional polishing slurry may be utilized in this process to remove a predetermined amount of material until reaching the specified wafer thickness range. In one embodiment, the staring wafer slice has a thickness range between 1.2-1.5 times the thickness of the final required thickness of the wafer slice. In step P270, the wafer slices are cleaned to remove any residual polishing fluids. This results in wafer slices with mirror-smooth wafer surface having very low LPDs.

Inspection on the wafer slices may be performed in step P280 with laser light scattering techniques. Table 1 below illustrates the LPDs counts of polished wafer slices that have undergone the MWTT and those that did not undergo the MWTT. The data demonstrates the advantages of mirror smooth polished wafers produced by the MWTT process. Inspection on the wafer slices is performed by TENCOR Surfscan® 6220 with threshold at 0.11 μm² and 0.3 μm. At 0.11 μm², the LPD count for wafer slices that undergone the MWTT process is less than 300, while the LPD count for wafer slices that did not undergo the MWTT process is more than 1000. At 0.3 μm², the LPD count for wafer slices that have undergone the MWTT process is less than 100, while the LPD count for wafer slices that did not undergo the MWTT process is more than 500.

TABLE 1
LPD Counts of Polished Wafers

| TENCOR Surfscan 6220 | Wafers with MWTT | Wafer without MWTT |
|---|---|---|
| Threshold 0.11 μm² | <300 | >1,000 |
| Threshold 0.3 μm² | <100 | >500 |

Although the above embodiments of the present invention relate to diffusing the impurities from the inner zone portions, such as the core of a wafer slice, to the outer zone portions, such as the surface and near-surface of the wafer slice, it is noted that arrangements of the components of the furnace and the position of the wafer slices as well as the thermal profile may be changed to diffuse the impurities from an inner zone portion represented by an inner circle of the wafer slice to an outer zone portion represented by the edge of the wafer slice. In this case, instead of polishing the front and back of the wafer slice, edge grinding is subsequently performed to remove impurities from the wafer slice.

FIG. 3 illustrates processes for loading wafer slices to be treated into a furnace according to an embodiment of the invention. In step P300, the wafer slices are loaded under a clean environment onto a wafer slices holder or carrier, preferably made of quartz. In one embodiment, the wafer holder is designed to eliminate any induced thermal stress. In the embodiment, the wafer slices holder has a low coefficient of thermal expansion that provides dimensional stability during the thermal treatment cycle. According to an embodiment of the invention, the configuration of the wafer slices holder is constructed to hold the wafer in a vertical position with minimal contact so as to reduce stress resulted from mismatch of thermal expansion between the wafer slices and holder material. Wafer slots should also have sufficient thickness tolerance to maintain a free position even at high temperature.

The quartz wafer slices holder is then loaded into a reaction tube/boat, preferably also made of quartz, in step P310. In one embodiment, the quartz tube is designed to provide uniform heat distribution during thermal treatment. In step P320, a prescribed amount of elemental arsenic is placed inside the quartz tube to provide arsenic overpressure at high temperature. At high temperature, the arsenic becomes vapor and exerts a pressure inside the quartz tube, and overpressure is achieved when a certain amount of arsenic is added at a specific temperature. This overpressure prevents the loss of arsenic atoms from the wafer slices and preserves the stoichiometry, meaning that the ratio of Ga to As, if a GaAs substrate is being treated, is substantially 1:1.

In step P330, the quartz tube with wafer slices and arsenic is evacuated by a vacuum pump to remove any residual moisture and gases. In one embodiment, the quartz tube is evacuated to a vacuum level of approximately 1×10⁻⁵ torr. In step P340, the quartz tube is sealed with a quartz cap to maintain the vacuum level. Finally, the sealed quartz tube assembly is loaded into a zone furnace in step P350. The zone furnace is capable of precise temperature control in different zones of the furnace. Thus, the temperature in the various locations of the quartz tube can be controlled.

FIG. 4 illustrates processes for controlling temperature inside the furnace with a thermal profile (for example, from 350-800 or 1000 degrees centigrade) to dissolve and relocate impurities within wafer slices according to an embodiment of the invention. The sealed quartz tube is heated with a specific temperature profile to control the arsenic vapor pressure during the thermal treatment. In step P400, the furnace is heated to a peak temperature, and in step P410, this peak temperature is held for a specific time duration. In one embodiment, the sealed quartz tube is heated to a temperature between 950 and 1,100° C. and hold for a specific amount of time ranging from 1 to 50 hours to cause the dissolution and the out-diffusion. For example, the wafer slices are heat treated up to approximately 1,000° C. in a sealed reaction tube, such as a quartz ampoule, under arsenic overpressure to dissolve impurities within bulk substrates and to allow the out-diffusion of excessive impurities to outer zone regions of the wafer slices.

In another example, power input is applied to the heating element of the furnace to heat the furnace to a peak temperature below the melting temperature of the semiconductor material, such as GaAs (Tₘ≈1238° C.), made up of the wafer slices. The peak temperature is then held for over 2 hours. In one embodiment, the peak temperature is between 0.8-0.9 times of the melting temperature of the semiconductor material.

In step P420, the furnace is cooled to an intermediate temperature in a pre-determined time duration, by for example, simply turning off the power source and allowing the furnace to cool to the intermediate temperature. In one embodiment, the sealed quartz tube is cooled slowly to reduce thermal stress and thermal shock to the wafer slices. The intermediate temperature is held for a specific duration, e.g., over 2 hours, to achieve temperature equilibrium. The intermediate temperature may, for example, be between 0.35 to 0.8 times of the peak temperature. In one embodiment, when the furnace reaches room temperature, the quartz tube is removed from the furnace and the wafer slices are removed from the quartz tube for subsequent treatments.

It should be emphasized that the above-described embodiments of the invention are merely possible examples of implementations set forth for a clear understanding of the principles of the invention. They are not intended to be exhaustive or to limit the invention to the precise forms disclosed. Variations and modifications may be made to the above-described embodiments of the invention without departing from the spirit and principles of the invention. For example, the same concept of the MWTT process may be applied to an n-type substrate, a p-type substrate, and a semi-insulating substrate. All such modifications and variations are intended to be included herein within the scope of the invention and protected by the following claims.

What is claimed is:

1. A method of treating a plurality of wafer slices having impurities, distributed uniformly within the wafer slices, the method comprising:
loading a predetermined amount of arsenic into a reaction tube containing the plurality of wafer slices;
loading the wafers into the reaction tube and sealing the reaction tube under vacuum;
loading the reaction tube into a furnace capable of having a plurality of zones;
controlling a temperature of the zones inside of the furnace with a predetermined thermal profile so that the impurities of the plurality of wafer slices are diffused from inner portions to outer portions of the plurality of wafer slices;
removing the plurality of wafer slices from the reaction tube; and
polishing the plurality of wafer slices to remove the outer portions of the plurality of wafer slices containing the impurities.

2. The method of claim 1, further comprising chemical etching the plurality of wafer slices before treating the plurality of wafer slices.

3. The method of claim 2, wherein the chemical etching is accomplished through at least one of an oxidizing agent and a complexing agent.

4. The method of claim 1, further comprising:
loading the plurality of wafer slices onto a wafer slices holder; and
loading the wafer slices holder into the reaction tube.

5. The method of claim 4, wherein the wafer slices holder comprises multiple slots, each slot holding a wafer slice in a vertical position.

6. The method of claim 5, wherein the wafer slice has a curved wafer edge, and the slot has a built-in radius that forms a curvature matching a curvature of said curved wafer edge of the wafer slice.

7. The method of claim 1, wherein the plurality of wafer slices are derived from at least one of n-type Gallium Arsenide (GaAs), p-type GaAs, and semi-insulating GaAs.

8. The method of claim 1, wherein the temperature profile comprises maintaining the furnace at a first temperature for a first time duration in one of the zones, the first temperature being below the melting temperature of the semiconductor material and maintaining the furnace at a second temperature for a second time duration in another of the zones, the second temperature being below the first temperature.

9. The method of claim 8, wherein the first temperature is 0.8 to 0.9 times the melting temperature of semiconductor material that makes up the plurality of wafer slices.

10. The method of claim 9, wherein the second temperature is 0.35 to 0.80 times the first temperature.

11. The method of claim 8, wherein the first duration is 1 to 50 hours.

12. The method of claim 8, wherein the second duration is 1 to 50 hours.

13. The method of claim 1, wherein each of the plurality of wafer slices in the reaction tube has a thickness range between 1.2 to 1.5 times the thickness of the polished wafer slices.

14. The method of claim 1, wherein the predetermined amount of arsenic loaded into the reaction tube has an amount sufficient to maintain adequate vapor pressure to preserve stoichiometric composition of semiconductor material that makes up the plurality of wafer slices.

15. The method of claim 1, wherein the reaction tube is a quartz tube.

16. The method of claim 1, further comprising
evacuating the reaction tube to remove at least one of residual moisture and gas after loading the arsenic into the reaction tube and before loading the reaction tube into the furnace; and
sealing the reaction tube after the above evacuation step.

17. The method of claim 16, wherein the reaction tube is evacuated to a vacuum level of about 1×10⁻⁵ Torr in the evacuation step, and this vacuum level is maintained by the sealing step.

18. A method of treating a plurality of substrates having impurities below surface regions of the substrates, the method comprising:
chemical treating the substrates;
loading the plurality of substrates onto a substrate holder;
loading the substrate holder into a reaction tube;
loading a predetermined amount of arsenic into the reaction tube;
evacuating the reaction tube to remove at least one of residual moisture and gas;
sealing the reaction tube under vacuum;
loading the sealed reaction tube into a furnace, wherein the furnace has multiple heat zones to control temperature in various locations of the quartz ampoule;
heating the sealed reaction tube with a specific temperature profile to effect dissolution of impurities and diffusion of the dissolved impurities to the surface regions of the substrates;
cooling the sealed reaction tube;
removing the plurality of substrates from the reaction tube; and
polishing the plurality of substrates to remove portion of the surface regions containing the impurities.

19. The method of claim 18, wherein the sealed reaction tube is heated to a temperature between 950-1,100° C. and held for a specific amount of time ranging from 1 to 50 hours.

20. The method of claim 18, wherein the plurality of substrates are a plurality of wafer slices.

21. The method of claim 18, wherein the plurality of substrates are derived from at least one of n-type GaAs, p-type GaAs, and semi-insulating GaAs.

22. The method of claim 18, wherein the predetermined amount of arsenic loaded into the reaction tube has an amount sufficient to maintain adequate vapor pressure to preserve stoichiometric composition of semiconductor material that makes up the plurality of substrates.

23. An apparatus for treating a plurality of wafer slices to reduce light point defects, comprising:
a zone furnace;
a reaction tube within the zone furnace;
arsenic repository in the reaction tube to allow a predetermined amount of arsenic to be placed into the reaction tube;
a wafer slices holder in the reaction tube, the wafer slices holder allowing a plurality of wafer slices to be held for treatment; and
a plurality of heating elements surrounding the reaction tube to control temperature of different zones inside of the zone furnace with a thermal profile.

24. The apparatus of claim 23, wherein each of the plurality of heating elements is annular in nature.

25. The apparatus of claim 23, wherein the predetermined amount of the arsenic to be placed into the reaction tube provides arsenic overpressure at high temperature and has an amount sufficient to maintain adequate vapor pressure to preserve stoichiometric composition of semiconductor material that makes up the plurality of wafer slices to be treated.

26. The apparatus of claim 23, wherein the thermal profile is created so that impurities that contribute to light point defects in the plurality of wafer slices to be treated are diffused to outer portions of the plurality of wafer slices.

27. The apparatus of claim 23, wherein the wafer slices holder comprises multiple slots, each slot holding a wafer slice to be treated in a vertical position.

28. The apparatus of claim 27, wherein the wafer slice to be treated has a curved wafer edge, and the slot has a built-in radius that forms a curvature matching a curvature of said curved wafer edge.

29. The apparatus of claim 23, wherein the apparatus is utilized to treat a plurality of wafer slices that are derived from at least one of n-type Gallium Arsenide (GaAs), p-type GaAs, and semi-insulating GaAs.

30. The apparatus of claim 23, wherein the reaction tube has an open sealable end and a closed end, and the arsenic repository is near the open end of the reaction tube.

31. The apparatus of claim 23, wherein the reaction tube is a quartz tube.

32. A method of treating semiconductor material, the method comprising:
loading a predetermined amount of arsenic into a reaction tube containing the semiconductor material, the arsenic providing arsenic overpressure at high temperature;
loading the reaction tube into a furnace;
controlling a temperature of different zones inside of the furnace with a thermal profile so that impurities of the semiconductor material are out-diffused to outer portions of the semiconductor material;
removing the semiconductor material from the reaction tube; and
polishing the semiconductor material to remove the outer zone portions of the semiconductor material containing impurities.

33. The method of claim 32, wherein the semiconductor material is a wafer.

34. The method of claim 32, further comprising treating the semiconductor material through chemical etching to remove surface contaminants.

35. The method of claim 32, further comprising:
loading the semiconductor material onto a holder;
loading the holder into the reaction tube; and
sealing the reaction tube.

36. The method of claim 35, wherein the holder comprises multiple slots, each slot holding semiconductor material in a vertical position.
